(19) United States
(12) Patent Application Publication
(10) Pub. No.: US 2007/0272292 A1
(43) Pub. Date: Nov. 29, 2007

(54) Thermal-recycling system for a motor vehicle

(75) Inventor: Cheng-Ju Tsai, Taipei City (TW)

Correspondence Address: COURTNEY STANIFORD & GREGORY LLP, P.O. BOX 9686, SAN JOSE, CA, 95157, US

(73) Assignee: Jerrei Lin

(21) Appl. No.: 11/440,559

(22) Filed: May 24, 2006

(51) Int. Cl. H01L 35/28

(52) U.S. Cl. 136/204

(57) ABSTRACT

A thermal-recycling system is adapted for use with a motor vehicle that has a heat generator generating heat when the motor vehicle is running. The terminal-recycling system includes a thermoelectric cooling module adapted to be in thermal communication with the heat generator for transforming the heat generated by the heat generator into electricity, and a power control unit connected electrically to the thermoelectric cooling module and a rechargeable battery and receiving the electricity from the thermoelectric cooling module so as to enable charging of the rechargeable battery using the electricity from the thermoelectric cooling module.

### BACKGROUND OF THE INVENTION

1. Field of the Invention

The invention relates to a thermal-recycling system, more particularly to a thermal-recycling system for a motor vehicle.

2. Description of the Related Art

At present, a cooling system is provided for a motor vehicle to adjust work temperature of an engine thereof to be within a normal temperature range from about 80° C. to 90° C. during running, thereby avoiding damage to the engine due to overheating.

Furthermore, after a motor vehicle is exposed to the sun for a period of time, the temperature inside the motor vehicle can rise up to about 50° C.-60° C. If someone gets in the motor vehicle, an air conditioning system of the motor vehicle is activated to lower the temperature inside the motor vehicle, thereby resulting in additional gasoline consumption. A current heat dissipating device is used for appropriately dissipating heat in a motor vehicle by means of solar energy or a battery as a power source supplied thereto. However, since the solar energy varies with incident direction and strength of sun light, and since the battery needs replacement, the current heat dissipating device for the motor vehicle is inconvenient during use.

### SUMMARY OF THE INVENTION

Therefore, the object of the present invention is to provide a thermal-recycling system for a motor vehicle that can overcome the aforesaid drawbacks of the prior art.

According to the present invention, there is provided a thermal-recycling system for a motor vehicle that has a heat generator. The heat generator generates heat when the motor vehicle is running. The terminal-recycling system comprises:

a thermoelectric cooling module adapted to be in thermal communication with the heat generator for transforming the heat generated by the heat generator into electricity;

a rechargeable battery; and

a power control unit connected electrically to the thermoelectric cooling module and the rechargeable battery and receiving the electricity from the thermoelectric cooling module so as to enable charging of the rechargeable battery using the electricity from the thermoelectric cooling module.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic circuit block diagram illustrating the preferred embodiment of a thermal-recycling system for a motor vehicle according to the present invention; and

FIG. 2 is a schematic diagram of the preferred embodiment when implemented in the motor vehicle.

### DETAILED DESCRIPTION OF THE PREFERRED EMBODIMENT

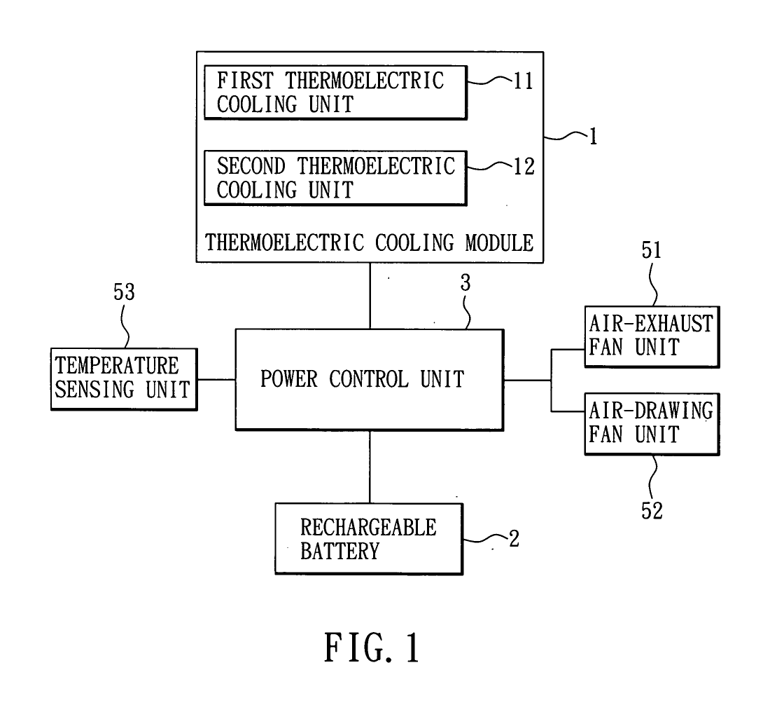

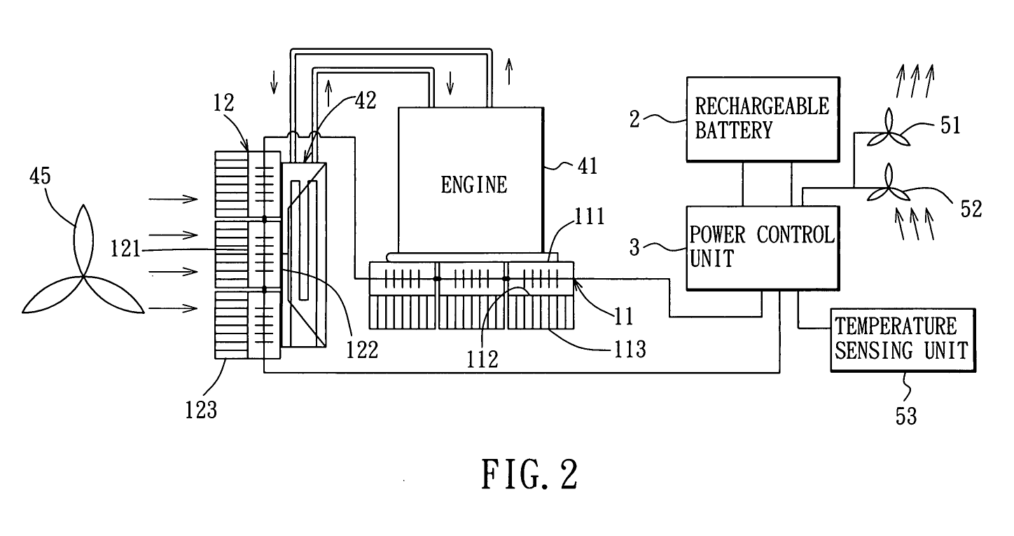

Referring to FIGS. 1 and 2, the preferred embodiment of a thermal-recycling system according to the present invention is shown to be adapted for use with a motor vehicle (not shown). The motor vehicle has a heat generator, which includes an engine 41 serving as a first heat source, and an engine cooling device 42 serving as a second heat source in this embodiment. The heat generator generates heat when the motor vehicle is running. The thermal-recycling system includes a thermoelectric cooling module 1, a rechargeable battery 2, a power control unit 3, a temperature sensing unit 53, an air-exhaust fan unit 51, and an air-drawing fan unit 52.

The thermoelectric cooling module 1 is adapted to be in thermal communication with the heat generator for transforming the heat generated by the heat generator into electricity. In this embodiment, the thermoelectric cooling module 1 includes first and second thermoelectric cooling units 11, 12.

The first thermoelectric cooling unit 11 includes a plurality of thermoelements, and has a first hot side 111 adapted to be in thermal communication with the engine 41, a first cold side 112 opposite to the first hot side 111, and a first heat sink 113 provided on the first cold side 112, as shown in FIG. 2. In this embodiment, the first hot side 111 is adapted for attachment to a bottom surface of the engine 41. As such, when the motor vehicle is running, the first hot side 111 receives the heat generated by the engine 41 so as to result in a temperature difference between the first hot and cold sides 111, 112 such that the first thermoelectric cooling unit 11 generates the electricity corresponding to the temperature difference between the first hot and cold sides 111, 112.

The second thermoelectric cooling unit 12 includes a plurality of thermoelements, and has a second hot side 121 adapted to be in thermal communication with the engine cooling device 42, a second cold side 122 opposite to the second hot side 121, and a second heat sink 123 provided on the second cold side 122, as shown in FIG. 2. In this embodiment, the second hot side 121 is adapted for attachment to a water tank of the engine cooling device 42. In addition, a heat-dissipating fan 45 of the engine cooling device 42 dissipates heat accumulated in the second heat sink 123. As such, when the motor vehicle is running, the second hot side 121 receives heat thermally conducted from the engine 41 so as to result in a temperature difference between the second hot and cold sides 121, 122 such that the second thermoelectric cooling unit 12 generates the electricity corresponding to the temperature difference between the second hot and cold sides 121, 122. The arrangement as such enhances the engine cooling efficiency.

The power control unit 3 is connected electrically to the thermoelectric cooling module 1 and the rechargeable battery 2, and receives the electricity from the first and second thermoelectric cooling units 11, 12 so as to enable charging of the rechargeable battery 2 using the electricity from the first and second thermoelectric cooling units 11, 12.

The air-exhaust fan unit 51 is connected electrically to the power control unit 3, and is adapted to be mounted in an air outlet (not shown) in the motor vehicle. The air-exhaust fan unit 51 is activated by the power control unit 3 by supplying electric power from the rechargeable battery 2 thereto to exhaust air from the inside of the motor vehicle to the outside.

The temperature sensing unit 53 is connected electrically to the power control unit 3, and is adapted to be disposed in the motor vehicle for sensing temperature inside the motor vehicle. The power control unit 3 controls supply of the electric power from the rechargeable battery 2 to the air-exhaust fan unit 51 according to the temperature sensed by the temperature sensing unit 53. The power control unit 3 enables activation of the air-exhaust fan unit 51 when the temperature sensed by the temperature sensing unit 53 is higher than a preset temperature.

The air-drawing unit 52 is connected electrically to the power control unit 3, and is adapted to be mounted in an air inlet (not shown) in the motor vehicle. The air-drawing fan unit 52 is activated by the power control unit 3 simultaneous with activation of the air-exhaust fan unit 51 to draw air into the motor vehicle.

In such a configuration, when the temperature inside the motor vehicle as sensed by the temperature sensing unit 53 is higher than the preset temperature, the power control unit 3 simultaneously activates the air-exhaust fan unit 51 and the air-drawing fan unit 52 by supplying the electric power from the rechargeable battery 2 thereto to promote air exchange between the inside and outside of the motor vehicle, thereby reducing effectively the temperature inside the motor vehicle. Since the electric power supplied by the rechargeable battery 2 to the air-exhaust fan unit 51 and the air-drawing fan unit 52 is pre-stored using the heat generated by the engine 41 and the engine cooling device 42 while the motor vehicle is running, the thermal-recycling system of the present invention is relatively convenient in power supply as compared to the aforesaid prior art, and conforms to environmental friendliness requirements.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A thermal-recycling system for a motor vehicle that has a heat generator, the heat generator generating heat when the motor vehicle is running, said terminal-recycling system comprising:
a thermoelectric cooling module adapted to be in thermal communication with the heat generator for transforming the heat generated by the heat generator into electricity;
a rechargeable battery; and
a power control unit connected electrically to said thermoelectric cooling module and said rechargeable battery and receiving the electricity from said thermoelectric cooling module so as to enable charging of said rechargeable battery using the electricity from said thermoelectric cooling module.

2. The thermal-recycling system as claimed in claim 1, further comprising an air-exhaust fan unit connected electrically to said power control unit and adapted to be mounted in an air outlet in the motor vehicle, said air-exhaust fan unit being activated by said power control unit by supplying electric power from said rechargeable battery thereto to exhaust air from the inside of the motor vehicle to the outside.

3. The thermal-recycling system as claimed in claim 2, further comprising a temperature sensing unit connected electrically to said power control unit and adapted to be disposed in the motor vehicle for sensing temperature inside the motor vehicle, said power control unit controlling supply of the electric power from said rechargeable battery to said air-exhaust fan unit according to the temperature sensed by said temperature sensing unit, said power control unit enabling activation of said air-exhaust fan unit when the temperature sensed by said temperature sensing unit is higher than a preset temperature.

4. The thermal-recycling system as claimed in claim 3, further comprising an air-drawing fan unit connected electrically to said power control unit and adapted to be mounted in an air inlet in the motor vehicle, said air-drawing fan unit being activated by said power control unit simultaneous with activation of said air-exhaust fan unit to draw air into the motor vehicle.

5. The thermal-recycling system as claimed in claim 1, wherein said thermoelectric cooling module includes a thermoelectric cooling unit that has a hot side adapted to be in thermal communication with the heat generating unit, and a cold side opposite to said hot side.

6. The thermal-recycling system as claimed in claim 5, wherein said thermoelectric cooling unit of said thermoelectric cooling module further has a heat sink provided on said cold side of said thermoelectric cooling unit.

7. The thermal-recycling system as claimed in claim 1, the heat generator including an engine serving as a first heat source, and an engine cooling device serving as a second heat source, wherein said thermoelectric cooling module includes:
a first thermoelectric cooling unit that has a first hot side adapted to be in thermal communication with the first heat source of the heat generator, and a first cold side opposite to said first hot side; and
a second thermoelectric cooling unit that has a second hot side adapted to be in thermal communication with the second heat source of the heat generator, and a second cold side opposite to said second hot side.

8. The thermal-recycling system as claimed in claim 7, wherein:
said first thermoelectric cooling unit of said thermoelectric cooling module further has a first heat sink provided on said first cold side thereof; and
said second thermoelectric cooling unit of said thermoelectric cooling module further has a second heat sink provided on said second cold side thereof.
